(19) United States
(12) Patent Application Publication
(10) Pub. No.: US 2025/0054128 A1
(43) Pub. Date: Feb. 13, 2025

(54) METHOD AND SYSTEM FOR OPTIMIZING OPTICAL INSPECTION OF PATTERNED STRUCTURES

(71) Applicant: NOVA LTD., Rehovot (IL)

(72) Inventor: Boaz BRILL, Rehovot (IL)

(73) Assignee: NOVA LTD., Rehovot (IL)

(21) Appl. No.: 18/789,627

(22) Filed: Jul. 30, 2024

Related U.S. Application Data
(63) Continuation of application No. 18/318,654, filed on May 16, 2023, now abandoned.
Application No. 18/318,654 is a continuation of application No. 17/064,652, filed on Oct. 7, 2020, now abandoned.
Application No. 17/064,652 is a continuation of application No. 16/571,120, filed on Sep. 15, 2019, now abandoned.
Application No. 16/571,120 is a continuation of application No. 15/902,150, filed on Feb. 22, 2018, now abandoned.
Application No. 15/902,150 is a continuation of application No. 15/050,613, filed on Feb. 23, 2016, now Pat. No. 9,904,993.
Application No. 15/050,613 is a continuation of application No. 13/704,780, filed on Feb. 21, 2013, now abandoned.
(60) Provisional application No. 61/355,571, filed on Jun. 17, 2010.

(51) Int. Cl. G06T 7/00; G01B 11/02; G01B 21/02; G03F 7/00; G06T 7/80

(52) U.S. Cl. CPC G06T 7/0004; G01B 11/02; G01B 21/02; G03F 7/70625; G06T 7/80; G01B 2210/56; G06T 2207/30148

(57) ABSTRACT

A system for use in metrology of a patterned structure, the system which includes a data input utility configured to receive: first type of data related to the patterned structure, the first type of data was obtained by a first type of metrology system and comprises first type measurements and first geometrical information regarding the patterned structure; second type of data related to the patterned structure, the second type of data was obtained by a second type of metrology system and comprises second type measurement results and second geometrical information regarding the patterned structure; the second type of metrology system differs from the first type of metrology system, and a data processing and analyzing utility configured to determine values of parameters of interest based on the first type of data and the second type of data. The parameters of interest comprise (i) a first parameter of interest that is related to the first type of metrology and (ii) a second parameter of interest that is related to the second type of metrology; in which the first parameter of interest is a parameter of a first model for interpreting the first type of measurements; in which the second parameter of interest is a parameter of a second model for interpreting the second type of measurements; wherein the data processing and analyzing utility is configured to determine values of parameters of interest by applying an iterative process, wherein the iterative process comprises updating the first model based on the second type of data to provide a currently updated first model and updating the second model based on the first type of data. The first type measurements and the second type measurements are taken from measurement sites of a substrate that comprises the patterned structure; wherein the data processing and analyzing utility configured to adjust the first type measurements by using correlation curves to provide adjusted first type measurements, and use the adjusted first type measurements during a data interpretation process applied on the second type of data, in which the data processing and analyzing utility is configured to reduce a number of floating parameters of the data interpretation process to provide a reduced number of floating parameters by stabilizing measurements of non-floating parameters; wherein each of the non-floating parameters has a greater impact on the first type measurements than an impact of each of the reduced number of floating parameters.

### FIELD OF THE INVENTION

This invention is generally in the filed of optical inspection, and relates to a method and system for optimizing optical inspection of patterned structures.

### BACKGROUND OF THE INVENTION

Semiconductor structures, such as integrated circuits, become more complicated in the dimensions and shapes of pattern features. Accordingly, there exists an increasing need in providing accurate measurements of full 3-dimensional structures, and in enabling these measurements to be applied to structures progressing on a production line, i.e. automatic inspection (metrology, defect detection, process control, etc.) of patterned structures.

Current metrology techniques heavily rely on test structures (which are typically produced in the scribe lines of a wafer) and on attempt to represent the process behavior inside the structure (which is not always successful). However, measuring directly the features inside the structure has a significant benefit as it allows both the relevance that test structures sometimes lack and the ability to map the changes across the structure.

Currently several metrology methods exist for the measurement of 2-dimensional (lines) and 3-dimensional structures. These methods can be roughly divided into four main groups including optical imaging techniques, beam scanning techniques, probe-based microscopy, and “non-imaging” optical techniques, usually termed scatterometry or optical critical dimension (OCD) measurement.

Optical imaging techniques are based on creation of a direct image of the region (area) of a sample. These techniques are in most cases no longer relevant for accurate geometrical measurements of such patterned structures as semiconductor wafers, because the features size of a pattern is much smaller than the wavelength used for imaging. This limitation may sometimes be overcome by utilizing aerial image of a mask taken prior to magnification down to the wafer, as done in some inspection tools (steppers).

Beam scanning techniques are based on scanning a given area of a sample with a focused beam of particles, collecting any kind of radiation produced by interaction between the beam and the sample (usually secondary particle emission), and using intensity (or other parameter) of the collected radiation to create a 2-dimensional image of the sample. Such techniques include, for example, SEM (Scanning Electron Microscopy) and Hellium Ion Beam Microscopy.

Probe-based microscopy utilizes a probe (tip) which is brought in close vicinity with the sample (such as for example in AFM—Atomic Force Microscopy) and scans a line or an area of the sample. Signals from the probe or, more often, feedback control signals (which are used to keep the probe at a constant distance from the sample) are used for creation of a 2-dimensional image of the sample.

Scatterometry or OCD techniques are based on measurement of diffraction from a repetitive structure on a sample (grating), having periodicity in either one or two directions, and reconstruction of the geometrical parameters of a unit cell of a pattern through solving the inverse problem, and fitting a model to the measurement results. Here, a measurement spot contains many periods of the repetitive structure, hence a measurement represents the average parameters across the measurement spot.

It should be noted that optical imaging techniques, beam scanning techniques and probe-based microscopy can all be implemented as scanning techniques and can create an image by scanning probe with high resolution (i.e. sensitive to a small part of the sample at a time) over the sample. As for the scatterometry or OCD techniques, they have several advantages, such as high speed and repeatability, but they usually suffer from a significant handicap which is the long setup time required before a measurement can be performed. This issue is more severe in case of 3-dimensional structures as they become more complex, because the number of parameters becomes larger and the diffraction calculation becomes longer.

One of the known approaches to circumvent the above issues is by combining information from additional sources, such as CD-SEM or AFM, for example as described in U.S. Pat. No. 6,650,424 assigned to the assignee of the present application. According to this technique scatterometry and SEM measurements are applied to a structure, and measured data indicative of, respectively, the structure parameters and lateral pattern dimensions of the structure are generated. The entire measured data are analyzed to enable using measurement results of the scatterometry for optimizing the measurement results of SEM and vice versa.

### GENERAL DESCRIPTION

There is a need in the art for facilitating inspection of patterned structures, including complex structures having a complex three-dimensional pattern.

It should be understood that for the purposes of this patent application, the term “inspection” should be interpreted broadly, including measurements, metrology and/or defect detection and/or process control/monitoring, etc. Also, in the description below, “imaging” scanning techniques, such as SEM, Hellium Ion Beam Microscopy, and AFM, are referred to as a scanning technique or system or tool, or metrology technique or system or tool, and should be distinguished from “non-imaging” technique such as scatterometry or OCD.

The present invention provides for optimizing creation of an optical model for describing/interpreting OCD measured data. In this connection, it should be understood that optical models are typically used for interpretation of optical measurements. Such optical model includes one or more functional representations of a dependence of an optical response from a structure on one or more structure-related parameters/conditions and parameters/conditions of a measurement system.

The present invention optimizes the optical model creation by optimizing creation of a geometrical model of the structure under measurements (being part of structure related data), on which the optical model is based. The present invention utilizes information (measured data) from any metrology tool of the kind providing (directly or indirectly) image data or bitmap of a sample to optimize modeling of OCD measurements, which reduces the setup time for complex 3-dimensional patterned structure and provides more accurate measurements. The image data may be provided. using measurements from a scanning tool (e.g. AFM, SEM, etc.). It should be noted that this optimization technique may be carried out off line or on line (real time), or a combined approach may be used.

In OCD techniques, one of the key steps is mathematical/theoretical representation of the geometry of a unit cell of a pattern in a manner that allows creation of a physical model (e.g. based on the principles of RCWA) for further interpretation of actual measured data. In most cases, the process of determination of the geometry of the unit cell is carried out during s recipe setup for each patterned layer in the structure. This is typically performed as follows: A user selects one or more unit cell geometries (geometrical models) from a given set of simple shapes (so-called “primitives”), adjusts the parameters of the selected primitive, and changes at least some of these parameters, e.g. center position and/or dimensions thereof. These steps might be repeated, if needed, until the unit cell can be sufficiently described for the physical model creation. Then, during the physical model creation/calculation based on the defined unit cell, suitable algorithms are used for performing the following: The current geometrical parameters are used to define the shape; discretization (slicing) is applied in a vertical (z) direction by slicing the features into several artificial layers, each containing a slightly different shape, and in lateral (x, y) directions; and the resulting, discretized structure is used to calculate a desired function (e.g. RCWA), such as electromagnetic response of a patterned structure, e.g. spectral response, diffraction pattern, etc.

However, the above process or similar processes currently used, suffer from the fact that the use of simple geometrical primitives does not allow to accurately describe the real geometry of the unit cell on the real structure (e.g. wafer). Additionally, the above process, apart from being in some cases time consuming, tends to produce a large set of parameters that are supposedly independent, while being in reality strongly correlated through the process behavior, e.g. size in x dimension and size in y dimension.

The present invention, according to its one aspect, provides a new approach, a so-called “hybrid approach” for optimizing OCD modeling based on data provided by imaging technique. As indicated above, an imaging tool is at times referred to herein as a scanning tool or a metrology tool. An example of the technique of the present invention is the use of data from a CD-SEM (metrology tool) for optimizing modeling of or measurements by an OCD, Scatterometry tool resulting in enhanced performance of either one or both of the metrology and CD measurements that cannot be obtained separately.

Thus, according to one broad aspect of the invention, there is provided a system for use in inspection of patterned structures, the system comprising: data input utility for receiving first type of data indicative of image data of at least a part of the patterned structure, and data processing and analyzing utility configured and operable for analyzing the image data, and determining a geometrical model for at least one feature of a pattern in said structure, and using said geometrical model for determining an optical model for second type of data indicative of optical measurements on a patterned structure.

In some embodiments of the invention, the data processing and analyzing utility comprises an identifier utility configured and operable for processing data indicative of said image data and determining a contour for at least one feature of the pattern, and a geometrical model creator utility connected to said identifier utility and operable for the determination of the geometrical model.

The data processing and analyzing utility may comprise an identifier utility configured and operable for processing the image data and identifying at least one unit cell comprising said at least one feature of the pattern, and generating said data to the contour identifier utility.

The system may also comprise a memory utility. The memory utility may serve for storing certain design rule data indicative of at least one feature of a pattern in said structure.

In some embodiments, the data processing and analyzing utility is configured and operable for receiving measured data of said second type and processing it for optimizing the first image data.

The image data may include measured data obtained by a scanning tool. The scanning tool may include a SEM and/or AFM tool.

In some embodiments, the second type of data corresponds to measured data obtainable by a scatterometry based tool.

According to another broad aspect of the invention, there is provided a measurement system comprising at least one measurement tool for obtaining measured data of at least one of the first and second types, and the above described system for the optical model creation configured for communicating with said at least one measurement tool.

According to yet another aspect of the invention, there is provided a scatterometry system comprising a measurement tool configured and operable for measuring on patterned structures and generating optical data of a second type, and the above-described system for the optical model creation.

According to yet further aspect of the invention, there is provided a method for use in inspection of patterned structures, the method comprising: receiving first type of data indicative of image data on at least a part of the patterned structure, processing and analyzing data indicative of the image data and determining a geometrical model for at least one feature of a pattern in said structure, using said geometrical model for determining an optical model for second type of data indicative of optical measurements on a patterned structure.

The determination of the geometrical model may comprise processing and analyzing data indicative of the received image data and determining a contour for at least one feature of the pattern, and processing said at least one contour for the determination of the geometrical model. The received image data may be first processed and analyzed for identifying at least one unit cell comprising said at least one feature of the pattern. To this end, certain design rule may be utilized providing data indicative of at least one feature of a pattern in said structure.

The method may operate for receiving measured data of said second type and processing it for optimizing the first image data.

The image data may include measured data obtained by a scanning tool. The latter may include SEM and/or AFM.

The second type of data may correspond to measured data obtainable by a scatterometry based tool.

The method may be used for inspection of semiconductor wafers.

According to yet another aspect of the invention, there is provided a method for use in inspection of patterned structures, the method comprising: receiving image data indicative of one or more images of at least a part of the patterned structure obtained by a scanning tool, processing and analyzing data indicative of said image data and determining a geometrical model for at least one feature of a pattern in said structure, using said geometrical model for determining an optical model for scatterometry based optical measurements on a patterned structure, thereby enabling use of said geometrical model for interpreting scatterometry based measurements applied to the patterned structure progressing on a production line.

### BRIEF DESCRIPTION OF THE DRAWINGS

In order to understand the invention and to see how it may be carried out in practice, embodiments will now be described, by way of non-limiting example only, with reference to the accompanying drawings, in which:

FIG. 1 is a schematic illustration of a simplified example of a unit cell suitable for OCD technique applied to patterned structures;

FIG. 2A exemplifies a system of the present invention for creation of an optical model for interpretation of optical measurements, e.g. OCD, on patterned structures based on image data provided by an imaging tool (metrology tool), for example SEM;

FIG. 2B exemplifies a method of the present invention for optical model creation based on identification of the unit cell from an image data obtained by a scanning tool, such as SEM;

FIG. 3 exemplifies the principles of a process of stretching/shrinking the contour of a feature in the unit cell for creation of geometrical model used in the method of FIG. 2B;

FIG. 4 exemplifies how the present invention is used for utilizing real-time OCD measurements for further optimizing the optical model previously created during an initial off line stage;

FIGS. 5 and 6 illustrate schematically how the principles of the present invention can be used for combining data from two measurement tools of different types for optimizing the optical model for use in interpretation of measured data from at least one of these tools: FIG. 5 illustrates an example where correlation parameters are found off line from SEM tool data and OCD tool data, and FIG. 6 shows an example where correlation parameters are obtained during a setup stage (e.g. from SEM data) and are then used to optimize real-time measurements (e.g. OCD measured data); and

FIG. 7 exemplifies a method of the invention for jointly optimizing data interpretation models of measurement tools of different types using measured data from both of these tools, by creating a combined model for both SEM and OCD measurements.

### DETAILED DESCRIPTION OF EMBODIMENTS

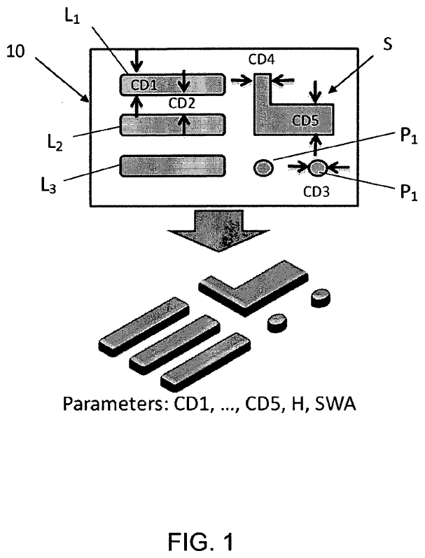

Reference is made to FIG. 1, illustrating a simplified example of a unit cell, generally designated 10, suitable for OCD technique applied to patterned structures. As shown, the unit cell 10 includes a pattern formed by spaced-apart features of different geometries (shapes and dimensions). In this specific but not limiting example, the features include three bars (lines) L₁, L₂ and L₃ characterized by the line width (critical dimension CD₁) and a space between the lines (critical dimension CD₂), two cylindrical elements (pins) P₁ and P₂ of a certain diameter (critical dimension CD₃), and an L-shaped feature S characterized by critical dimensions CD₄ and CD₅. It should be understood that the unit cell may have any other configuration, and the unit cell shown in the figure would practically be characterized by additional parameters, such as side wall angle (SWA), the line width profile, height, etc.

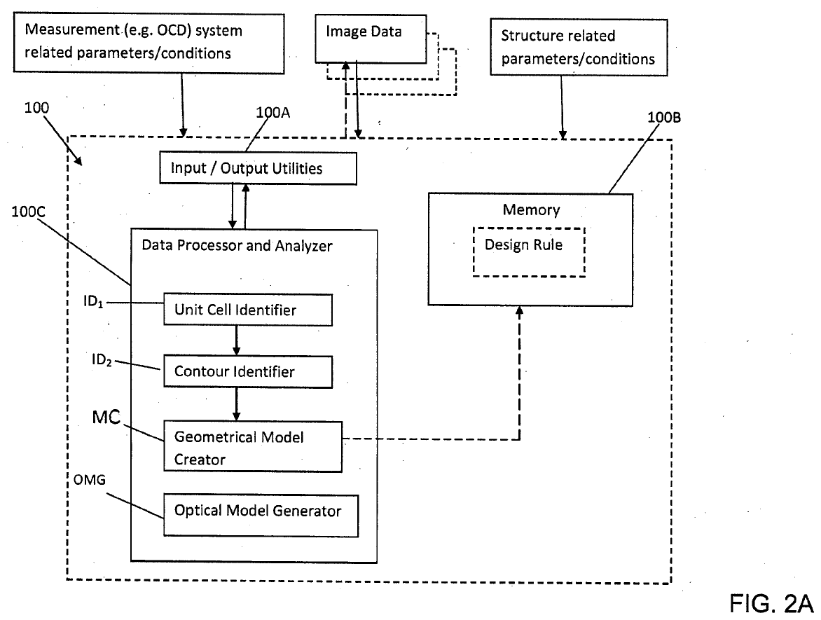

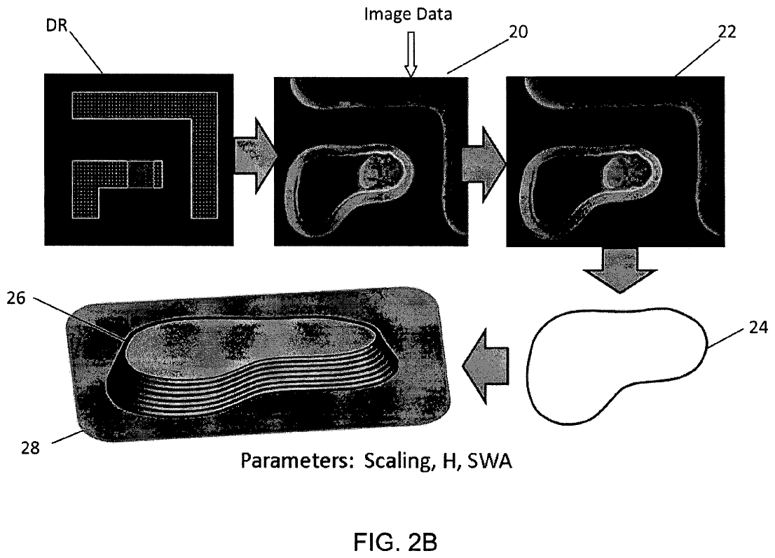

FIGS. 2A and 2B exemplify system and method respectively of the present invention for creation of an optical model for interpretation of optical measurements on patterned structures based on image data provided by an imaging tool (metrology tool), for example SEM. This modeling process provides for utilizing image data corresponding to a 2-dimensional image obtained by the imaging tool to optimize operation of an OCD tool. It should be noted that the modeling may be carried out on line (in real time) by directly processing image data from the imaging tool, or off line utilizing image data from a storage device. As for the OCD optimization procedure, it also may be either a real-time process, as part of continuous measurement (automatic inspection) of structures progressing on a production line, or off line procedure (e.g. as part of recipe setup), or a combination of both. The simplest example of the off line mode is by using a single scanning tool image for the recipe setup of an OCD tool. The recipe setup process of such a simple example is schematically illustrated in FIG. 2B.

The process is performed by a modeling system, generally designated 100, of the invention. The system 100 is typically a computer system having inter alia data input and output utilities 100A, memory utility 100B, and data processing and analyzing utility 100C. The system may include a data presentation utility, such as display. The data input/output may be configured for receiving/transmitting data appropriately formatted for wireless communication with other devices. In this specific but not limiting example, The data processing and analyzing utility 100C includes identifier modules ID₁ and ID₂ (software and/or hardware utilities), a geometrical model creator MC (software and/or hardware utility), and an optical data generator OMG.

The identifier module ID₁ is preprogrammed for receiving and processing input image data and identifying unit cell(s); identifier module ID₂ is operable for processing the unit cell related data (received from module ID₁) and identifying contours for at least some of the features in the unit cell(s). The final model creator receives the contour-data and analyzes it to determine and apply a suitable morphological function and thereby create an appropriate physical model.

Thus, the system receives input image data. The latter is obtained by a scanning tool (e.g. SEM) and being indicative of a 2-dimensional image (top view) of a patterned structure or part thereof. The image data may be entered by user or received from another device (e.g. imaging tool or storage) directly or via wireless communication. The system may optionally be provided with certain design rule data DR including inter alia information about the unit cell. The system (its data processing and analyzing utility) is preprogrammed for processing the image data (while utilizing the design rule or not) for automatically identifying possible unit cells based on identified repetitions of patterned features (step 20). The case might be such that the system “suggests” several options for the unit cell, and a user chooses the correct option (i.e. a combination of automatic and manual modes for the identification of unit cell). Then, the system operates for processing image data of the unit cell for automatically identifying the contours of all or at least one of the features within the unit cell, a single such contour C being shown in the figure (step 22), and then operates to extract the contour related data/image (step 24). The system utilizes the contour related data C for determining a 3-dimensional shape 26 of the respective feature (step 28).

Optionally, the user can fine-tune the parameters of the contour detection algorithm to select a sub-set of features, e.g. in order to use only the contours related to features that reside in a specific (e.g. uppermost) layer of the patterned structure, as opposed to other features visible in the image.

The so-determined 3-dimensional shape 26 is then further processed for creating a geometrical model for further generation of the optical model for use in interpretation of OCD measurements. This process may include determination of a morphological function, which serves for imitating an effect of changing the feature (e.g. under varying process conditions) and/or a difference between the extracted contour and the real edge of the feature. The user may define parameter range(s) for the morphological function to be used for changing (stretching/shrinking) the contour during the calculation. The user may define additional geometrical parameters, e.g. structure related parameters such as side wall angle, underlying layers, etc.

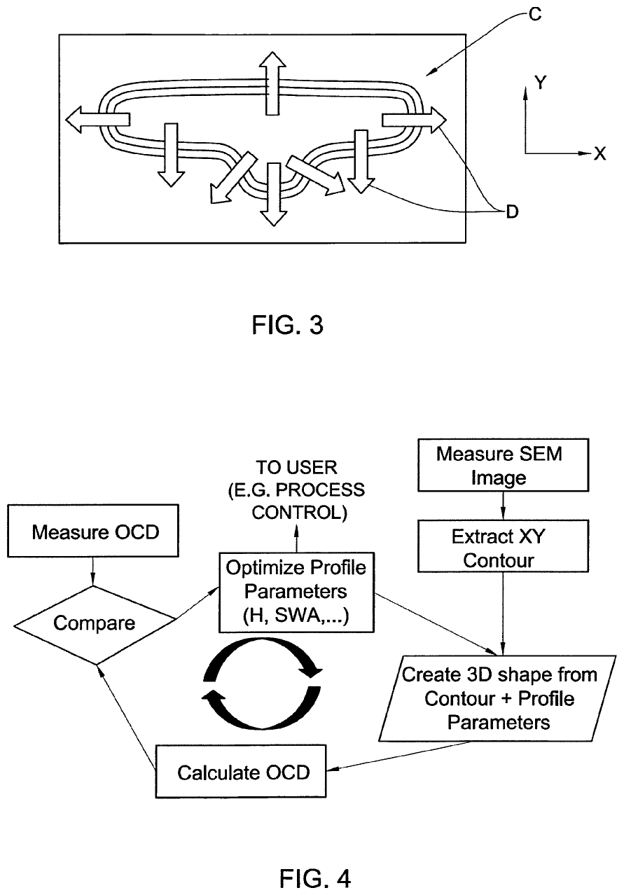

A non-limiting example of the process of stretching/shrinking the contour (applying the morphological function) for the purposes of creation of geometrical model is shown in FIG. 3. In this example, the morphological function acts to stretch the contour C orthogonal to the local directions, generally at D, of the normal to the different segments of the contour. The local shift of the contour could be affected by several parameters, such as an overall average shift (overall “scaling” factor or delta-CD), the local direction of the contour (anisotropy of a parameter change, e.g. different delta-CDₓ and delta-CD_{y}), the local curvature of the contour (dealing differently with internal corners and external corners), etc. In most cases, the user may define only the range of the general delta-CD, while other parameters are default or already known through previously set recipes.

Another example for defining the morphological function may be as follows: One or more detection algorithms of contour identification may be applied several times on the same image data, each time with different parameters of the algorithm, e.g. threshold level values, thus obtaining a set of contours. Then, the system, being an expert system (self-learning system) is trained to find the morphological function using this set of contours.

Yet another example for finding a suitable morphological function may utilize multiple images or simulated image data pieces for the patterned structures or parts thereof having different pattern parameters corresponding to different process parameters/conditions, e.g. a lithographical process performed with different focus and exposure conditions. As a result, a set of contours is obtained from these multiple image data pieces, and the system is trained to find the morphological function. It should be noted that in this case if the images are obtained as a function of multiple process conditions, e.g. as a function of both focus and exposure, then the resulting morphological function can in turn be a function of those parameters/conditions. This property can be later used during interpretation of the actual OCD measurements (as part of the fitting process) for directly determine the process parameters/conditions from the measured data.

Turning back to FIGS. 2A and 2B, the module OMG can operate as follows to generate an appropriate optical model for use in interpretation of OCD measurements. The module OMG utilizes the geometrical model, based on the shape of the features defined by the contour, and the current value(s) of the morphological function parameters and additional parameters as described above. The module OMG is preprogrammed for simulating a diffraction signature of the determined geometrical model for given conditions (measurement system related parameters/conditions and structure related parameters/conditions), including inter alia illumination and detection channels' parameters/conditions, including but not limited to wavelengths, numerical aperture of illumination/collection, azimuth and elevation of illumination/collection, polarization of light, etc. To this end, geometrical model creator MC operates for transforming the shape of feature(s) to a discrete form, including multiple layers and discrete values for x and y; the transformation can be done using discretization in the lateral (x, y) directions. The OMG model may utilize any suitable known method (e.g. RCWA) for diffraction calculation.

The so-obtained optical model can then be used for interpreting actual measured data. This process includes a fitting (inverse problem) procedure, either using real-time-regression method or using a library method. The problem parameters include the values of the morphological function and of the additional parameters, in order to enable determination of the structure parameter(s) based on the best matching condition (based on the fitted parameters). The overall scaling factor, e.g. delta-CD, can then be correlated to measurements done by other techniques and/or to process conditions (e.g. exposure), and Statistical Process Control (SPC) charts can be used to allow process control.

It should be noted that in some cases more than one different effect cannot be optimally described by one morphological function. It would be in such case an advantage to compose several morphological functions operating successively on the contour, e.g. a function describing differences between the contour and the actual feature boundaries (correcting errors in the scanning tool and the contour detection algorithm) and another function describing the expected changes of the feature with a change in process parameters. It should also be noted that morphological transformations referred to herein as “scaling”, although mathematically such transformation may or may not be pure scaling (i.e. (x,y)→(ax,ay)); therefore for the purposes of the present application the term “scaling” should be interpreted broader, meaning any transformation function.

As indicated above, the invention may utilize input image data including a set of multiple images of the structure corresponding to multiple sets of process conditions, e.g. a focus-exposure matrix (FEM), used for the structure manufacture. In this case, the contour identification is performed for the entire set of images. In this case, the suitable morphological function is that which corresponds to continuous transformation of a certain reference contour to any of the other contours. The reference contour may for example be that corresponding to the process parameter or parameters' set, e.g. focus and exposure, in the middle of the predefined range for said parameter or parameters' set. In addition, scaling can be applied through an additional morphological function, as described above. This procedure advantageously provides that the parameters of the inverse diffraction problem explicitly include the process parameters. Hence, by performing a fitting of measured signals to the optical model (either by regression or using a library method), one can directly get not only the measured shape most fitting to the measured data but also the process parameters most likely to correspond to the measured data. This kind of information is specifically useful for process control as there is no need to make any additional transformation once a correction needs to be applied, i.e. deviation between the standard process parameters and the resulting process parameters directly indicate how should the process be tuned to get back to the desired feature shape and profile.

It should be noted that the sensitivity of measurements to the focus and exposure conditions may be enhanced by using specially designed targets. These may for example be targets having many sharp edges, e.g. a 2-dimensional array of diamond shapes, which shape is extremely sensitive to focus conditions as the sharp features are printing correctly only very close to optimal focus conditions. A structure consisting of many spaces that are close to the minimum space possible in a given manufacturing process may be highly sensitive to exposure conditions. Thus, combining information from several different sites containing different targets, e.g. one having high sensitivity to focus and the other having high sensitivity to exposure, more accurate information about exact full exposure conditions can be provided.

As indicated above, the present invention provides for using image(s) from a scanning tool as part of the measurement process itself (on line modeling), as well as during setup (off line modeling). The on line modeling advantageously allows for removing the concern regarding morphological changes in the contour that are not accommodated by the scaling function and for eliminating the need to fit the scaling function over a wide range. If the scaling factor has been accurately and reliably characterized during the setup procedure, then by fitting data in various process conditions, the scaling factor could then be either fixed or allowed to change in a very small window of uncertainty, thereby reducing the number of floating parameters and simplifying the fitting process during the actual measurements.

In the above-described examples, image data from a scanning tool (e.g. SEM) was used to optimize OCD measurements. As also described above, this procedure may utilize both off line modeling and on line (real time) modeling, i.e. OCD measurements (real time measurements) are used for further optimizing the model created during the initial off line stage. This is illustrated schematically, in a self-explanatory manner, in FIG. 4. As shown, measured SEM image is processed to determine the contour for each feature in the unit cell and crate a geometrical model (3-shape of at least some features of the unit cell). This data is used for generating optical model for the OCD measurements. Independently, OCD measured data is provided in real time, and interpreted by comparison with the optical model data (fitting procedure), resulting in determination of optimal structure parameters (e.g. height, SWA, etc.). These parameters are output, e.g. to user for the purposes of process control. Concurrently, these parameters are used to optimize the geometrical model and accordingly further optimize the optical model.

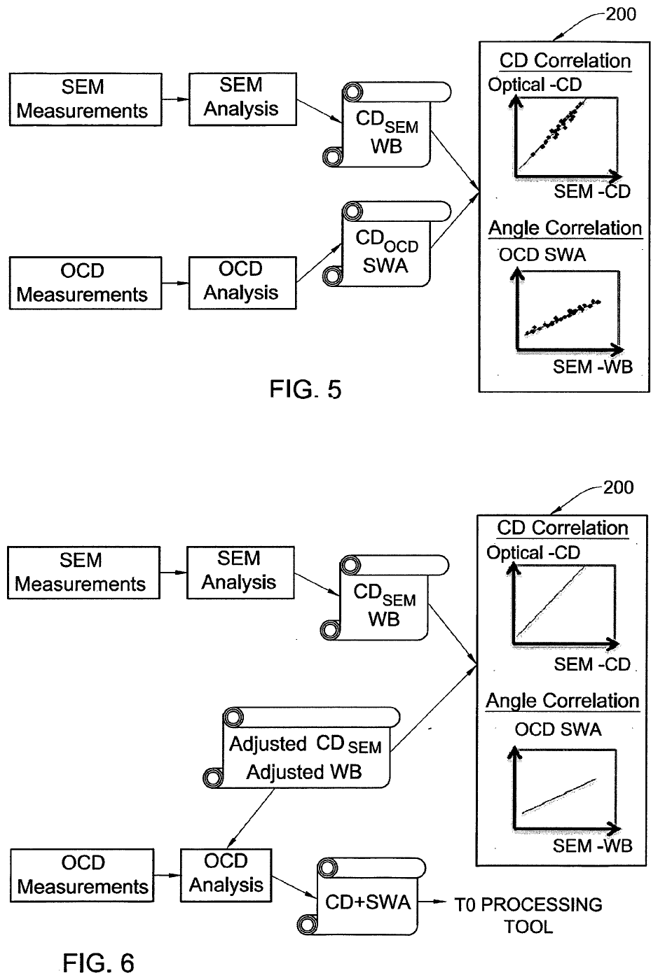

The invention, in its yet other aspect, provides for combining data from two measurement tools of different types (operating on different physical principles), i.e. “imaging” and “non-imaging” types, such as respectively, CD-SEM and OCD. This is exemplified schematically in FIGS. 5 and 6. As shown in the figures, SEM and OCD tools operate independently to provide measured data pieces indicative of respectively critical dimensions (CD_{SEM}) and wide-band width (WB), and CD_{OCD} and side wall angle (SWA). These parameters are input into a modeling (computing) system 200. The system 200 may be a computer system including inter alia data input and output utilities, memory utility, and data processing and analyzing utility, as well as data presentation utility (e.g. display). The data processing and analyzing utility in this case is configured and operable to process the input data and determine correlation curves for the critical dimensions measured by SEM and OCD tools, i.e. Optical-CD and SEM-CD, and for SB and SWA parameters, i.e. OCD-angle and SEM-WB. By this, correlation curves or correlation functions are determined, and correlation parameters, mainly slope and offset, are obtained. For example, CD values found by OCD can be correlated to CD values found by CD-SEM and Side Wall Angle values found by OCD can be correlated by White-Band width values found by CD-SEM. In order to verify correct correlation coefficients, it is best practice to perform the setup using a set of measurements representing a wide range of process conditions, e.g. for lithography process a Focus/Exposure matrix. In the example of FIG. 5, the correlation parameters are found off line, and can then be used for optimizing interpretation of OCD measurements, e.g. in case the parameter of interest, such as SWA of photoresist, is a weak parameter (i.e. parameter that affects the measured data, i.e. OCD spectra, less that other “strong” parameters.

FIG. 6 shows how the correlation parameters obtained during the setup stage (FIG. 5) are used to optimize the OCD measurements, i.e. analysis of OCD measured data. As shown, correlation data is used to determine correlated or adjusted value of CDSEM and WB. These adjusted parameters are input into a control unit of the OCD station and used for optimizing the calculation of CD and SWA parameters.

Thus, during mass production of patterned structures such as semiconductor wafers, measurements can be taken from some or all of the sites in the structure by both OCD and SEM tools, and the measured data of one tool (e.g. the CD-SEM) can be adjusted by using correlation curves, and then the adjusted values can be used for the data interpretation process of the other tool (e.g. the OCD). By performing the above correlation and adjustment, the number of floating parameters in the second measurement can be reduced, thus enabling more stable measurement of the remaining parameters, e.g. “weak” parameters.

It should be noted that in order to reduce noise in the first measured data and thus reduce its effect on the interpretation of the second measured data, a so-called “soft injection” method can be used. This can be performed as follows: The second measurement (e.g. by OCD tool) is first performed with no prior knowledge based on the first measurement, e.g. CD-SEM. Then, an error function that might exist in the second measurement is reduced using a penalty function concept. This technique may be similar to that described in the International patent application No. PCT/IL2011/000188, assigned to the assignee of the present application, which application is incorporated herein by reference. More specifically, a penalty function is determined and added to the error function of the optimization process, favoring the measurement results to be similar to the (adjusted) values obtained from the first (CD-SEM) measurement. Such a penalty function may be for example proportional to the squared difference between the two measurements. The optimization process continues until a certain convergence condition is achieved, using a target function that includes both the original error function and the penalty function. This process advantageously provides for tuning the “strength” of the penalty function, thus reducing the amplification of noise in the first measurement on the final result.

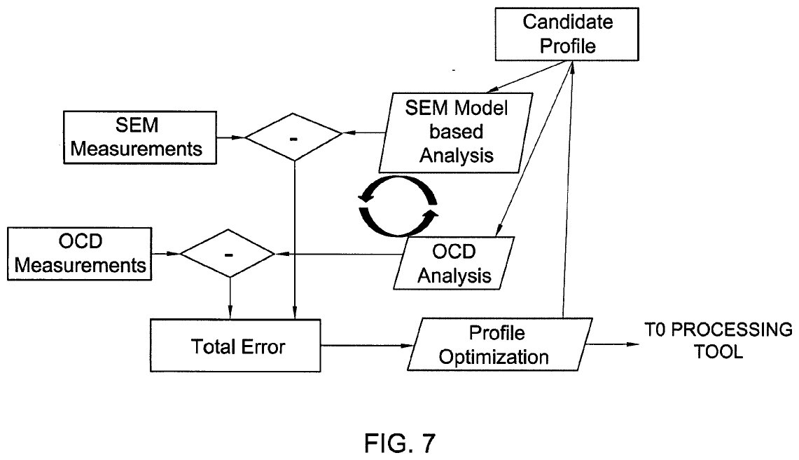

The present invention, in its yet further aspect, provides for jointly optimizing data interpretation models of measurement tools of different types using measured data from both of these tools. This is illustrated schematically in FIG. 7. In this case, a combined model including both the SEM and OCD measurements is created. The process starts from a common “candidate profile”, being certain theoretical data (knowledge, prediction) about the profile of a patterned structure, e.g. at least one feature of unit cell. The candidate profile is used for simulating the OCD data (optical response) and the SEM data (image) based on corresponding predefined models for data analysis. The so-obtained simulated OCD and SEM data are compared (by fitting) to corresponding measured data and an error is (residual error, Merit Function) determined for each measurement. The two residual errors are combined to a total error, which is minimized in a profile optimization process by iteratively adjusting the candidate profile. The profile corresponding to a minimal total error is selected to be output to the process tool or fab host, as a measurement of the profile and used for process control.

Thus, in this case, both measurement techniques (e.g. OCD and SEM) are assumed to utilize model based interpretation. The optimization is done concurrently for both measurement tools by assuming at each step of the iterative optimization process a single geometrical profile (3-D structure) and simulating the expected response for each of the tools using its own physical model. The simulated data are then compared to the measured data yielding error functions for each of the tools. The separate error functions are combined into a single Total Error figure. The optimization process is then acting to minimize the Total Error through modifying the parameters of the common geometrical profile until convergence. By combining the two (or possibly any number) channels in this way, the information that resides in each of the measurements can be fully utilized without a need to extract the results from the realm of a single physical interaction operating in one measurement tool and into the realm of another physical interaction acting in the other tool, thus avoiding potential “translation” problems.

It should be understood that running the combined interpretation using a large or sufficiently diversified set of examples enables optimization of the specific models. In the case of OCD, the model can be optimized towards a correct setting of fixed parameters, either geometric of parameters related to the optical properties of materials involved in the structure. In the case of SEM model, using the additional information obtained through the above process the model can be tuned for example with respect to the efficiency of extraction of secondary electrons from different depths, different materials, geometries, etc.

The present invention provides for combining measurements of different tools (different types of measurements) while performing the measurements on different sites of the structure. Such combination can be beneficial for various reasons. For example, it allows for increasing the overall sampling across a given wafer, as well as allows for sampling different wafers in a lot, and for measuring both inside the die, on a device, and in the scribe line on a test pattern while linking the two.

In order to be able to utilize measurements coming from different locations an additional element may be used, i.e. a model for the behavior of parameters across the wafer/die/lot. Once a model is defined, a link can be created between different measurements by penalizing results that are far away from the model (similar to the “soft injection” explained above) and the full data set, including measurements done on different locations can be re-analyzed. The whole process may be repeated until the full data set converges to minimum (stable results). Through this process information can flow between measurements done on different locations, enabling the benefits explained above.

We claim:

1. A system for use in metrology of a patterned structure, the system comprising:
a data input utility configured to receive:
(a) first type of data related to the patterned structure, the first type of data was obtained by a first type of metrology system and comprises first type measurements and first geometrical information regarding the patterned structure;
(b) second type of data related to the patterned structure, the second type of data was obtained by a second type of metrology system and comprises second type measurement results and second geometrical information regarding the patterned structure; the second type of metrology system differs from the first type of metrology system; and
a data processing and analyzing utility configured to determine values of parameters of interest based on the first type of data and the second type of data;
wherein the parameters of interest comprise (i) a first parameter of interest that is related to the first type of metrology and (ii) a second parameter of interest that is related to the second type of metrology:
wherein the first parameter of interest is a parameter of a first model for interpreting the first type of measurements;
wherein the second parameter of interest is a parameter of a second model for interpreting the second type of measurements;
wherein the data processing and analyzing utility is configured to determine values of parameters of interest by applying an iterative process, wherein the iterative process comprises updating the first model based on the second type of data to provide a currently updated first model and updating the second model based on the first type of data;
wherein the first type measurements and the second type measurements are taken from measurement sites of a substrate that comprises the patterned structure;
wherein the data processing and analyzing utility configured to adjust the first type measurements by using correlation curves to provide adjusted first type measurements, and use the adjusted first type measurements during a data interpretation process applied on the second type of data;
wherein the data processing and analyzing utility is configured to reduce a number of floating parameters of the data interpretation process to provide a reduced number of floating parameters by stabilizing measurements of non-floating parameters; wherein each of the non-floating parameters has a greater impact on the first type measurements than an impact of each of the reduced number of floating parameters.

2. The system according to claim 1, wherein the updating of the first model comprises optimizing the first model, and wherein the updating of the second model comprises optimizing the second model.

3. The system according to claim 1, wherein the first type of metrology system is an imaging metrology system and wherein the second type of metrology system is a non-imaging metrology system.

4. The system according to claim 1, wherein the second type of metrology system is a helium ion beam microscopy system.

5. The system according to claim 1, wherein the second type of metrology system is an atomic force microscope.

6. The system according to claim 1, wherein the first type of metrology system is a scatterometry metrology system.

7. The system according to claim 1, wherein the first type of metrology system is an optical critical dimension (OCD) metrology system and wherein the second type of metrology system is a scanning electron microscope (SEM).

8. The system according to claim 7, wherein the first type of data comprises critical dimension (CD) values obtained by the OCD metrology system, the second type of data comprises CD values obtained by the SEM, wherein the data processing and analyzing utility are configured to determine the values of parameters of interest by correlating between the CD values obtained by the OCD metrology system and the CD values obtained by the SEM.

9. The system according to claim 7, wherein the first type of data comprises side wall angle (SWA) values obtained by the OCD metrology system, the second type of data comprises SWA values obtained by the SEM, wherein the data processing and analyzing utility are configured to determine the values of parameters of interest by correlating between the SWA values obtained by the OCD metrology system and the SWA values obtained by the SEM.

10. The system according to claim 1 wherein the data processing and analyzing utility is configured to minimize a total error figure that is a sum of an error function related to the first model and an error function related to the second model.

11. A method for use in metrology of a patterned structure, the method comprising:
receiving, by a data input utility: a first type of data related to the patterned structure, the first type of data was obtained by a first type of metrology system and comprises first type measurements and first geometrical information regarding the patterned structure; and a second type of data related to the patterned structure, the second type of data was obtained by a second type of metrology system and comprises second type measurement results and second geometrical information regarding the patterned structure; the second type of metrology system differs from the first type of metrology system; and
determining, by a data processing and analyzing utility, values of parameters of interest based on the first type of data and the second type of data; wherein the parameters of interest comprise (i) a first parameter of interest that is related to the first type of metrology and (ii) a second parameter of interest that is related to the second type of metrology; wherein the first parameter of interest is a parameter of a first model for interpreting the first type of measurements; wherein the second parameter of interest is a parameter of a second model for interpreting the second type of measurements;
wherein the determining, by the data processing and analyzing utility, of the values of parameters of interest comprises applying an iterative process, wherein the iterative process comprises updating the first model based on the second type of data to provide a currently updated first model, and updating the second model based on the first type of data;
wherein the first type measurements and the second type measurements are taken from measurement sites of a substrate that comprises the patterned structure;
wherein the method comprises:
adjusting the first type measurements by using correlation curves to provide adjusted first type measurements;
using the adjusted first type measurements during a data interpretation process applied on the second type of data; and
reducing a number of floating parameters of the data interpretation process to provide a reduced number of floating parameters by stabilizing measurements of non-floating parameters;
wherein each of the non-floating parameters has a greater impact on the first type measurements than an impact of each of the reduced number of floating parameters.

12. The system according to claim 1, wherein the updating of the first model comprises optimizing the first model, and wherein the updating of the second model comprises optimizing the second model.

13. The system according to claim 1, wherein the first type of metrology system is an imaging metrology system and wherein the second type of metrology system is a non-imaging metrology system.

14. The system according to claim 1, wherein the second type of metrology system is a helium ion beam microscopy system.

15. The system according to claim 1, wherein the second type of metrology system is an atomic force microscope.

16. The system according to claim 1, wherein the first type of metrology system is a scatterometry metrology system.

17. The system according to claim 1, wherein the first type of metrology system is an optical critical dimension (OCD) metrology system and wherein the second type of metrology system is a scanning electron microscope (SEM).

18. The system according to claim 17, wherein the first type of data comprises critical dimension (CD) values obtained by the OCD metrology system, the second type of data comprises CD values obtained by the SEM, wherein the method comprising determining the values of parameters of interest by correlating between the CD values obtained by the OCD metrology system and the CD values obtained by the SEM.

19. The system according to claim 17, wherein the first type of data comprises side wall angle (SWA) values obtained by the OCD metrology system, the second type of data comprises SWA values obtained by the SEM, wherein the method comprising determining the values of parameters of interest by correlating between the SWA values obtained by the OCD metrology system and the SWA values obtained by the SEM.

20. The system according to claim 11, comprising minimizing a total error figure that is a sum of an error function related to the first model and an error function related to the second model.

21. A non-transitory computer readable medium for use in metrology of a patterned structure, the non-transitory computer readable medium stores instructions executable by a processor for:
receiving, by a data input utility: a first type of data related to the patterned structure, the first type of data was obtained by a first type of metrology system and comprises first type measurements and first geometrical information regarding the patterned structure; and a second type of data related to the patterned structure, the second type of data was obtained by a second type of metrology system and comprises second type measurement results and second geometrical information regarding the patterned structure; the second type of metrology system differs from the first type of metrology system; and
determining, by a data processing and analyzing utility, values of parameters of interest based on the first type of data and the second type of data; wherein the parameters of interest comprise (i) a first parameter of interest that is related to the first type of metrology and (ii) a second parameter of interest that is related to the second type of metrology; wherein the first parameter of interest is a parameter of a first model for interpreting the first type of measurements; wherein the second parameter of interest is a parameter of a second model for interpreting the second type of measurements;
wherein the determining, by the data processing and analyzing utility, of the values of parameters of interest comprises applying an iterative process, wherein the iterative process comprises updating the first model based on the second type of data to provide a currently updated first model, and updating the second model based on the first type of data;
wherein the first type measurements and the second type measurements are taken from measurement sites of a substrate that comprises the patterned structure;
wherein the method comprises:
adjusting the first type measurements by using correlation curves to provide adjusted first type measurements;
using the adjusted first type measurements during a data interpretation process applied on the second type of data; and
reducing a number of floating parameters of the data interpretation process to provide a reduced number of floating parameters by stabilizing measurements of non-floating parameters;
wherein each of the non-floating parameters has a greater impact on the first type measurements than an impact of each of the reduced number of floating parameters.
